(19) United States
(12) Patent Application Publication
(10) Pub. No.: US 2024/0194827 A1
(43) Pub. Date: Jun. 13, 2024

(54) LIGHT EMITTING DEVICE AND PROJECTOR

(71) Applicant: SEIKO EPSON CORPORATION, Tokyo (JP)

(72) Inventor: Masamitsu MOCHIZUKI, CHINO-SHI (JP)

(73) Assignee: SEIKO EPSON CORPORATION, Tokyo (JP)

(21) Appl. No.: 18/534,682

(22) Filed: Dec. 10, 2023

(30) Foreign Application Priority Data
Dec. 13, 2022 (JP) 2022-198661

(51) Int. Cl. H01L 33/18; G03B 21/20; H01L 33/60

(52) U.S. Cl. CPC H01L 33/18; G03B 21/2033; H01L 33/60

(57) ABSTRACT

A light emitting device including a first semiconductor layer, a second semiconductor layer, a light emitting layer disposed between the first semiconductor layer and the second semiconductor layer, and a photonic crystal layer disposed on a side of the second semiconductor layer opposite to the light emitting layer is provided. The photonic crystal layer includes a first region provided with a first photonic crystal that causes light emitted by the light emitting layer to resonate in a direction orthogonal to a laminating direction of the first semiconductor layer and the light emitting layer and does not cause the light to be emitted in a direction different from the orthogonal direction, and a second region provided with a second photonic crystal that does not overlap the first region when viewed in the laminating direction and causes the light to be emitted in a direction different from the orthogonal direction.

The present application is based on, and claims priority from JP Application Serial Number 2022-198661, filed Dec. 13, 2022, the disclosure of which is hereby incorporated by reference herein in its entirety.

### BACKGROUND

### 1. Technical Field

The present disclosure relates to a light emitting device and a projector.

### 2. Related Art

A photonic crystal surface emitting laser (PCSEL) utilizing a photonic crystal effect is known.

For example, JP-A-2007-208127 describes a PCSEL in which a distributed feedback control photonic crystal and a surface emission control photonic crystal are superimposed. The distributed feedback control photonic crystal is configured such that light propagating through an active layer serving as a core is subjected to two-dimensional distributed feedback within a plane of the active layer and is not emitted in a direction perpendicular to the active layer. The surface emission control photonic crystal is configured such that propagating light is emitted in a direction perpendicular to an active layer.

However, in the PCSEL described in JP-A-2007-208127, holes forming the surface emission control photonic crystal are disposed between adjacent holes forming the distributed feedback control photonic crystal. For that reason, the light subjected to the distributed feedback by the distributed feedback control photonic crystal is scattered by the holes constituting the surface emission control photonic crystal, which results in a loss.

### SUMMARY

One aspect of a light emitting device according to the present disclosure includes:
a first semiconductor layer having a first conductivity type;
a second semiconductor layer having a second conductivity type different from the first conductivity type;
a light emitting layer disposed between the first semiconductor layer and the second semiconductor layer; and
a photonic crystal layer provided on a side of the second semiconductor layer opposite to the light emitting layer, wherein
the photonic crystal layer includes:
a first region provided with a first photonic crystal that causes light emitted by the light emitting layer to resonate in a direction orthogonal to a laminating direction of the first semiconductor layer and the light emitting layer and does not cause the light to be emitted in a direction different from the orthogonal direction; and
a second region provided with a second photonic crystal that does not overlap the first region when viewed in the laminating direction and causes the light emitted by the light emitting layer to be emitted in a direction different from the orthogonal direction.

One aspect of a projector according to the present disclosure includes the one aspect of the light emitting device.

### BRIEF DESCRIPTION OF THE DRAWINGS

FIG. 1 is a plan view schematically showing a light emitting device according to the present embodiment.

FIG. 2 is a cross-sectional view schematically showing the light emitting device according to the present embodiment.

FIG. 3 is a cross-sectional view schematically showing a manufacturing process of the light emitting device according to the present embodiment.

FIG. 4 is a cross-sectional view schematically showing a light emitting device according to a first modified example of the present embodiment.

FIG. 5 is a plan view schematically showing a light emitting device according to a second modified example of the present embodiment.

FIG. 6 is a plan view schematically showing a light emitting device according to a third modified example of the present embodiment.

FIG. 7 is a plan view schematically showing the light emitting device according to the third modified example of the present embodiment.

FIG. 8 is a diagram schematically showing a projector according to the present embodiment.

FIG. 9 is a diagram schematically showing a projector according to a modified example of the present embodiment.

### DESCRIPTION OF EMBODIMENTS

Preferred embodiments of the present disclosure will be described in detail below with reference to the drawings. Also, the embodiments described below do not unduly limit the content of the present disclosure described in the claims. In addition, not all the configurations described below are essential constituent elements of the present disclosure.

### 1. Light Emitting Device

### 1.1. Configuration

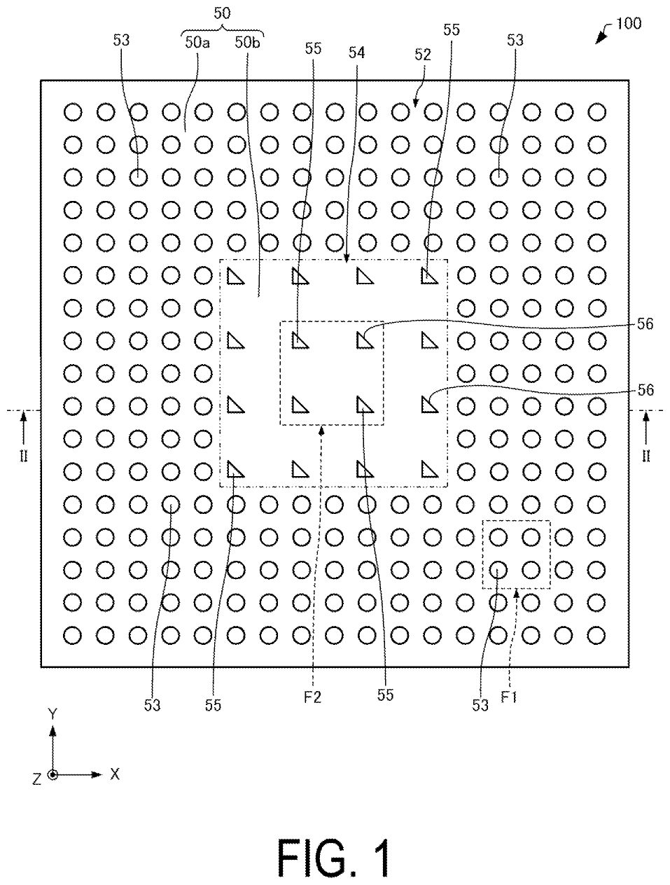

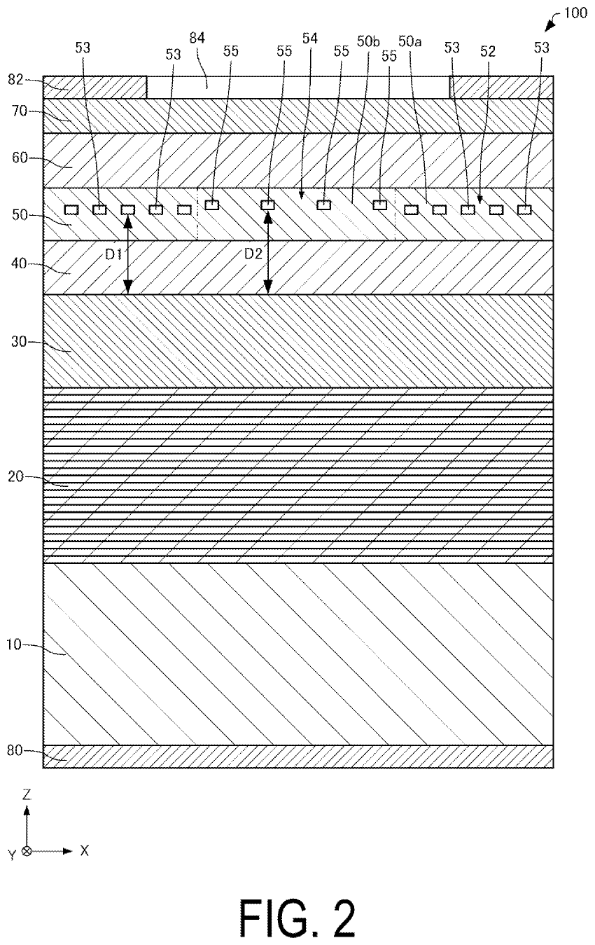

First, a light emitting device according to the present embodiment will be described with reference to the drawings. FIG. 1 is a plan view schematically showing a light emitting device 100 according to the present embodiment. FIG. 2 is a cross-sectional view along line II-II in FIG. 1, which schematically shows the light emitting device 100 according to the present embodiment. In addition, FIGS. 1 and 2 illustrate an X axis, a Y axis, and a Z axis as three axes orthogonal to each other.

As shown in FIGS. 1 and 2, the light emitting device 100 includes, for example, a substrate 10, a first semiconductor layer 20, a light emitting layer 30, a second semiconductor layer 40, a photonic crystal layer 50, a third semiconductor layer 60, a contact layer 70, a first electrode 80, and a second electrode 82. The light emitting device 100 is a PCSEL. Also, for the sake of convenience, illustration of members other than the photonic crystal layer 50 is omitted in FIG. 1.

The substrate 10 has, for example, a first conductivity type. The first conductivity type is, for example, n-type. The substrate 10 is, for example, an n-type GaAs substrate doped with Si.

As shown in FIG. 2, the first semiconductor layer 20 is provided on the substrate 10. The first semiconductor layer 20 is provided between the substrate 10 and the light emitting layer 30. The first semiconductor layer 20 has, for example, an n-type conductivity. The first semiconductor layer 20 is, for example, a distributed Bragg reflector (DBR) in which a high refractive index layer and a low refractive index layer having a refractive index lower than that of the high refractive index layer are alternately laminated. The high refractive index layer is, for example, a Si-doped n-type Al_{0.1}Ga_{0.9}As layer. The low refractive index layer is, for example, a Si-doped n-type Al_{0.9}Ga_{0.1}As layer. The number of high refractive index layers and low refractive index layers is not particularly limited. The first semiconductor layer 20 reflects light generated in the light emitting layer 30 toward the contact layer 70 side.

In the present specification, the description will be made in a way that, in a direction in which the first semiconductor layer 20 and the light emitting layer 30 are laminated (simply referred to as a “laminating direction” below), when the light emitting layer 30 is used as a reference, a direction from the light emitting layer 30 toward the second semiconductor layer 40 is defined as “upward”, and a direction from the light emitting layer 30 toward the first semiconductor layer 20 is defined as “downward”. In the illustrated example, the laminating direction is the Z axis direction. In addition, a direction orthogonal to the laminating direction is also referred to as an “in-plane direction”.

The light emitting layer 30 is provided on the first semiconductor layer 20. The light emitting layer 30 is provided between the first semiconductor layer 20 and the second semiconductor layer 40. The light emitting layer 30 generates light when an electric current is injected thereinto. The light emitting layer 30 has, for example, a well layer and a barrier layer. The well layer and the barrier layer are i-type semiconductor layers which are not doped with impurities intentionally. The well layer is, for example, a GaAs layer or an InGaAs layer. The barrier layer is, for example, an AlGaAs layer (for example, AlₓGa₁₋ₓAs layer, 0.1≤x≤0.3). The light emitting layer 30 has a multiple quantum well (MQW) structure configured of the well layer and the barrier layer.

Also, the number of well layers and barrier layers forming the light emitting layer 30 is not particularly limited. For example, only one well layer may be provided. In this case, the light emitting layer 30 has a single quantum well (SQW) structure.

The second semiconductor layer 40 is provided on the light emitting layer 30. The second semiconductor layer 40 is provided between the light emitting layer 30 and the photonic crystal layer 50. The second semiconductor layer 40 has a second conductivity type different from the first conductivity type. The second conductivity type is, for example, p-type. The second semiconductor layer 40 is, for example, a p-type AlGaAs layer (for example, Al_{0.5}Ga_{0.5}As layer) doped with C (carbon).

The photonic crystal layer 50 is provided on the second semiconductor layer 40. The photonic crystal layer 50 is provided on a side of the second semiconductor layer 40 opposite to the light emitting layer 30. The photonic crystal layer 50 is provided between the second semiconductor layer 40 and the third semiconductor layer 60. The photonic crystal layer 50 is configured of a semiconductor layer, and first holes 53 and second holes 55 formed in the semiconductor layer. The semiconductor layer is, for example, a C-doped p-type GaAs layer. The first holes 53 and the second holes 55 may be holes or may be filled with, for example, p-type InGaP.

The photonic crystal layer 50 has a first region 50a provided with a first photonic crystal 52 and a second region 50b provided with a second photonic crystal 54. As shown in FIG. 1, the first region 50a surrounds the second region 50b when viewed in the laminating direction. The second region 50b does not overlap the first region 50a when viewed in the laminating direction. In the illustrated example, the second region 50b has a square shape.

The first photonic crystal 52 surrounds the second photonic crystal 54 when viewed in the laminating direction. The first photonic crystal 52 has a plurality of first holes 53 arranged periodically. The first photonic crystal 52 is configured of the plurality of first holes 53, and the semiconductor layer between adjacent first holes 53.

The first holes 53 of the first photonic crystal 52 have, for example, rotational symmetry when viewed in the laminating direction. In the illustrated example, shapes of the first holes 53 are circles. The plurality of first holes 53 are arranged, for example, in a square lattice pattern in the X axis direction and the Y axis direction. A basic shape F1 of the plurality of first holes 53 forming the first photonic crystal 52 has, for example, rotational symmetry. In the illustrated example, the shape F1 is configured of four circles (2×2 cycles).

The first photonic crystal 52 causes the light generated in the light emitting layer 30 to resonate in the in-plane direction. The first photonic crystal 52 performs distributed feedback (diffraction in the in-plane direction) of the light generated in the light emitting layer 30 using odd-order diffraction, preferably first-order diffraction. By performing the distributed feedback using the first-order diffraction, the first photonic crystal 52 can more strongly confine the light propagating in the in-plane direction within the plane. For that reason, even if a distance D1 between the first holes 53 and the light emitting layer 30 is increased, the light generated in the light emitting layer 30 can be resonated in the in-plane direction. By increasing the distance D1, reliability of the light emitting layer 30 can be improved. The distance D1 is, for example, at least 50 nm and at most 500 nm, preferably at least 100 nm and at most 300 nm. By performing the distributed feedback using the first-order diffraction, firstly, light loss due to out-of-plane diffraction does not occur, and thus out-of-plane light loss is reduced. Secondly, it is possible to inhibit the light propagating in a +X axis direction from cancelling out respective light components reflected in a −X axis direction at refractive index interfaces forming the first photonic crystal 52, specifically, for example, at a surface on which light propagating in the +X axis direction is incident toward any first hole 53 and at a surface from which the light transmitted through the surface is emitted from the first hole 53.

Since the first photonic crystal 52 uses the odd-order diffraction for the distributed feedback, the light generated in the light emitting layer 30 is not diffracted in a direction orthogonal to the in-plane direction. The first photonic crystal 52 does not diffract the light generated in the light emitting layer 30 in the laminating direction.

The second photonic crystal 54 has a plurality of second holes 55 arranged periodically. The second photonic crystal 54 is configured of the plurality of second holes 55 and a semiconductor layer between adjacent second holes 55. When viewed in the laminating direction, the shapes of the first holes 53 are different from shapes of the second holes 55.

The second holes 55 of the second photonic crystal 54 do not have, for example, rotational symmetry when viewed in the laminating direction. In the illustrated example, the shapes of the second holes 55 are isosceles right triangles. The second holes 55 each have an inclined surface 56 inclined at 45° with respect to the X axis and the Y axis. The plurality of second holes 55 are arranged, for example, in a square lattice pattern. A basic shape F2 of the plurality of second holes 55 forming the second photonic crystal 54 does not have rotational symmetry, for example. In the illustrated example, the shape F1 is configured of four isosceles right triangles (2×2 cycles). A pitch of the plurality of second holes 55 is different from a pitch of the plurality of first holes 53. In the illustrated example, the pitch of the plurality of second holes 55 is larger than the pitch of the plurality of first holes 53.

Also, a “pitch of holes” is a distance between centers of adjacent holes in a predetermined direction. A “center of a hole” is a center of a circle when a planar shape of the hole is a circle, and is a center of a minimum inclusion circle when the planar shape of the hole is not a circle. For example, when a planar shape of a hole is a polygon, a center of the hole is a center of the smallest circle including the polygon inside, and when the planar shape of the hole is an ellipse, the center of the hole is a center of the smallest circle including the ellipse inside.

The second photonic crystal 54 can cause the light generated in the light emitting layer 30 to be emitted in a direction different from the in-plane direction. For example, the second photonic crystal 54 emits the light generated in the light emitting layer 30 in the laminating direction. The second photonic crystal 54 emits the light generated in the light emitting layer 30 in the laminating direction using, for example, first-order diffraction. Also, the second photonic crystal 54 may emit the light generated in the light emitting layer 30 in a direction oblique to the laminating direction using, for example, third-order diffraction. The second photonic crystal 54 may also diffract the light generated in the light emitting layer 30 in the in-plane direction.

As shown in FIG. 2, for example, a distance D2 between the second holes 55 of the second photonic crystal 54 and the light emitting layer 30 is larger than the distance D1 between the first holes 53 of the first photonic crystal 52 and the light emitting layer 30. Thus, reliability of a portion of the light emitting layer 30 overlapping the second photonic crystal 54 can be maintained. Specifically, for example, it is possible to inhibit occurrence of dislocations in this region and the dislocations reaching the light emitting layer 30 over time.

Also, although not illustrated, the distance D1 may be smaller than the distance D2. Thus, it is possible to increase an intensity of the light emitted in the laminating direction while maintaining the reliability of the portion of the light emitting layer 30 overlapping the first photonic crystal 52. Further, the distance D1 and the distance D2 may be the same. Thus, the first holes 53 and the second holes 55 can be easily manufactured.

As shown in FIG. 2, the third semiconductor layer 60 is provided on the photonic crystal layer 50. The third semiconductor layer 60 is provided between the photonic crystal layer 50 and the contact layer 70. A material of the third semiconductor layer 60 is, for example, the same as that of the second semiconductor layer 40. A distance between the light emitting layer 30 and the contact layer 70 can be increased by the third semiconductor layer 60. Thus, absorption of the light generated in the light emitting layer 30 by the contact layer 70 can be reduced.

The contact layer 70 is provided on the third semiconductor layer 60. The contact layer 70 is provided between the third semiconductor layer 60 and the second electrode 82. The contact layer 70 overlaps the first region 50a and the second region 50b when viewed in the laminating direction. The contact layer 70 overlaps the first photonic crystal 52 and the second photonic crystal 54 when viewed in the laminating direction.

The contact layer 70 is, for example, a C-doped p-type GaAs layer. A concentration of impurities of the contact layer 70 is higher than concentrations of impurities of the second semiconductor layer 40, the photonic crystal layer 50, and the third semiconductor layer 60. A resistivity of the contact layer 70 is lower than resistivities of the second semiconductor layer 40, the photonic crystal layer 50, and the third semiconductor layer 60.

The first electrode 80 is provided under the substrate 10. The substrate 10 is provided between the first electrode 80 and the first semiconductor layer 20. The substrate 10 may be in ohmic contact with the first electrode 80. The first electrode 80 is electrically coupled to the first semiconductor layer 20 via the substrate 10. For the first electrode 80, for example, a layer including a Ti layer, an Au layer, a Pt layer, and an Au layer laminated in order from the substrate 10 side is used. The first electrode 80 is one electrode for injecting an electric current into the light emitting layer 30.

The second electrode 82 is provided on the contact layer 70. The contact layer 70 may be in ohmic contact with the second electrode 82. The second electrode 82 is electrically coupled to the second semiconductor layer 40 via the contact layer 70, the third semiconductor layer 60, and the photonic crystal layer 50. For the second electrode 82, for example, a layer including a Ti layer, an Al layer, and an Au layer laminated in order from the contact layer 70 side is used. The second electrode 82 is the other electrode for injecting an electric current into the light emitting layer 30.

An opening portion 84 is formed in the second electrode 82. The opening portion 84 overlaps the second photonic crystal 54 when viewed in the laminating direction. The second electrode 82 overlaps the first photonic crystal 52 when viewed in the laminating direction.

### 1.2. Operations

In the light emitting device 100, a pin diode is configured by the p-type second semiconductor layer 40, the i-type light emitting layer 30, and the n-type first semiconductor layer 20. In the light emitting device 100, when a forward bias voltage of the pin diode is applied between the first electrode 80 and the second electrode 82, an electric current is injected into the light emitting layer 30 to cause recombination of electrons and holes in the light emitting layer 30. This recombination causes light emission. The light generated in the light emitting layer 30 propagates through the light emitting layer 30 while receiving a gain and resonates in the in-plane direction due to the distributed feedback effect of the first photonic crystal 52 and the second photonic crystal 54 (diffraction in the in-plane direction in each photonic crystal), thereby causing laser oscillation.

The laser-oscillated light is emitted in a direction different from the in-plane direction due to the photonic crystal effect of the second photonic crystal 54. The second photonic crystal 54 emits the laser-oscillated light in the laminating direction using, for example, first-order diffraction. The light directed toward the first semiconductor layer 20 side is reflected by the first semiconductor layer 20 and emitted from the contact layer 70 side. The light emitting device 100 emits the light from the opening portion 84.

In the example shown in FIG. 1, when viewed in the laminating direction, the first holes 53 of the first photonic crystal 52 are arranged in a square lattice pattern in the X axis direction and the Y axis direction, and the second holes 55 of the second photonic crystal 54 each have the inclined surface 56 inclined at 45° with respect to the X axis and the Y axis. For that reason, in the second photonic crystal 54, the resonance in the X axis direction and the resonance in the Y axis direction can be coupled to each other, and the two-dimensional resonance of the light can be strengthened.

Also, although not illustrated, the light emitting device 100 may be mounted on a mounting substrate (not shown) in a junction-down manner. In this case, the first semiconductor layer 20 may not form a DBR, and the second semiconductor layer 40 or the third semiconductor layer 60 may form a DBR.

Also, although the InGaAs-based light emitting layer 30 has been described above, various materials capable of emitting light when an electric current is injected can be used for the light emitting layer 30 in accordance with a wavelength of the emitted light. For example, InGaN-based, AlGaN-based, AlGaAs-based, InGaAsP-based, InP-based, GaP-based, AlGaInP-based semiconductor materials can be used.

### 1.3. Effects

For example, when the distributed feedback control photonic crystal and the surface emission control photonic crystal are superimposed and the holes forming the surface emission control photonic crystal are disposed between the adjacent holes forming the distributed feedback control photonic crystal, the original periodicity is not maintained in the distributed feedback control photonic crystal. In this case, since two types of photonic crystal structures are mixed in the same region in a plan view, at least one of the photonic crystals does not retain its original periodic structure due to the influence of the other photonic crystal, which results in scattering loss.

The light emitting device 100 includes the first semiconductor layer 20 having the first conductivity type, the second semiconductor layer 40 having the second conductivity type different from the first conductivity type, the light emitting layer 30 provided between the first semiconductor layer 20 and the second semiconductor layer 40, and the photonic crystal layer 50 provided on the side of the second semiconductor layer 40 opposite to the light emitting layer 30. The photonic crystal layer 50 includes the first region 50a provided with the first photonic crystal 52 that causes the light emitted by the light emitting layer 30 to resonate in the in-plane direction and does not cause the light to be emitted in the direction different from the in-plane direction, and the second region 50b provided with the second photonic crystal 54 that does not overlap the first region 50a when viewed in the laminating direction and causes the light emitted by the light emitting layer 30 to be emitted in the direction different from the in-plane direction.

For that reason, in the light emitting device 100, it is possible to reduce scattering of the light caused to resonate by the first photonic crystal 52 due to the second photonic crystal 54, that is, scattering loss due to the fact that the original periodicity of the first photonic crystal 52 is not maintained. This makes it possible to inhibit an increase in threshold value and a decrease in slope efficiency.

Further, in the light emitting device 100, since the two photonic crystals 52 and 54 are used, the light generated in the light emitting layer 30 has multiple wavelengths. For that reason, the influence of speckles can be reduced.

Further, the light emitting device 100 can individually control and optimize the first photonic crystal 52 that causes the light generated in the light emitting layer 30 to resonate in the in-plane direction and the second photonic crystal 54 that causes the light generated in the light emitting layer 30 to be emitted in the direction different from the in-plane direction.

Further, in the light emitting device 100, since the light is not emitted from the region overlapping the first photonic crystal 52 when viewed in the laminating direction, it is possible to cause the light to resonate efficiently with correspondingly low loss. For that reason, the laser oscillation can be performed in a smaller area. For that reason, for example, when a plurality of light emitting devices 100 are arranged in arrays, an interval between the arrays becomes small, and the intensity of the light can be adjusted for each small area.

In the light emitting device 100, the second photonic crystal 54 causes the light generated in the light emitting layer 30 to be emitted in the laminating direction. For that reason, in the light emitting device 100, the light generated in the light emitting layer 30 can be emitted using first-order diffraction.

The light emitting device 100 has the second electrodes 82 and the contact layer 70 provided between the photonic crystal layer 50 and the second electrodes 82, and when viewed in the laminating direction, the contact layer 70 overlaps the first region 50a and the second region 50b. For that reason, in the light emitting device 100, it is possible to increase the intensity of the light resonating in the in-plane direction due to the first photonic crystal 52, for example, as compared with a case in which the contact layer does not overlap the first region.

In the light emitting device 100, the first region 50a surrounds the second region 50b when viewed in the laminating direction. For that reason, in the light emitting device 100, the light resonating in the in-plane direction due to the first photonic crystal 52 can be efficiently guided to the second photonic crystal 54.

In the light emitting device 100, when viewed in the laminating direction, the shapes of the first holes 53 have rotational symmetry, and the shapes of the second holes 55 do not have rotational symmetry. For that reason, in the light emitting device 100, it is possible to inhibit non-luminous spots caused by light canceling out each other due to excessively good symmetry immediately above the light emitting device 100.

### 2. Method for Manufacturing Light Emitting Device

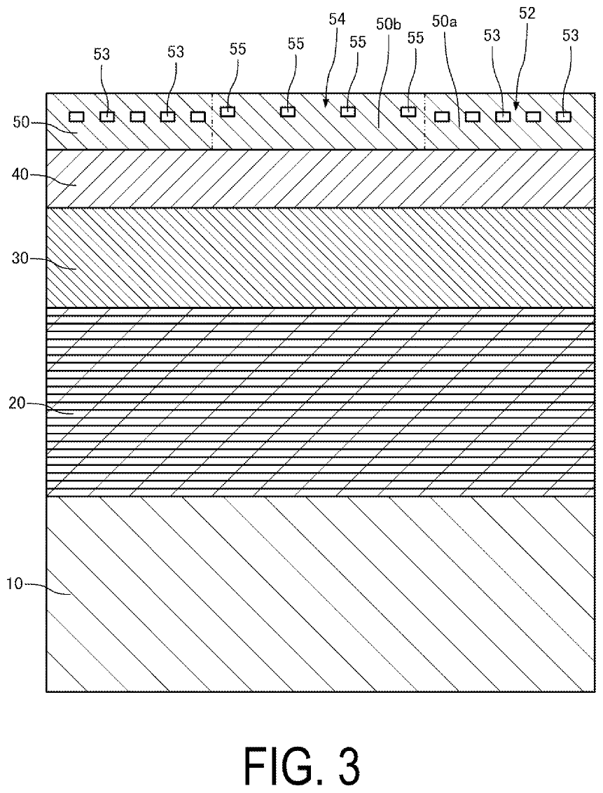

Next, a method for manufacturing the light emitting device 100 according to the present embodiment will be described with reference to the drawings. FIG. 3 is a cross-sectional view schematically showing a manufacturing process of the light emitting device 100 according to the present embodiment.

As shown in FIG. 3, the first semiconductor layer 20, the light emitting layer 30, and the second semiconductor layer 40 are epitaxially grown on the substrate 10 in order. Examples of the epitaxial growth method include a metal organic chemical vapor deposition (MOCVD) method, a molecular beam epitaxy (MBE) method, and the like.

Next, the photonic crystal layer 50 is epitaxially grown on the second semiconductor layer 40. During the epitaxial growth of the photonic crystal layer 50, patterning is performed to form the first holes 53 and the second holes 55. Thus, the photonic crystal layer 50 having the first photonic crystal 52 and the second photonic crystal 54 can be formed. Examples of the epitaxial growth method include an MOCVD method, an MBE method, and the like. The patterning is performed, for example, by photolithography and etching, or electron beam lithography and etching.

As shown in FIG. 2, the third semiconductor layer 60 and the contact layer 70 are epitaxially grown in order on the photonic crystal layer 50. Examples of the epitaxial growth method include an MOCVD method, an MBE method, and the like.

Next, the first electrode 80 is formed under the substrate 10. Next, the second electrode 82 is formed at the contact layer 70. The first electrode 80 and the second electrode 82 are formed by, for example, a vacuum deposition method or a sputtering method. Also, the order of forming the first electrode 80 and the second electrode 82 is not particularly limited.

The light emitting device 100 can be manufactured through the above process.

### 3. Modified Examples of Light Emitting Device

### 3.1. First Modified Example

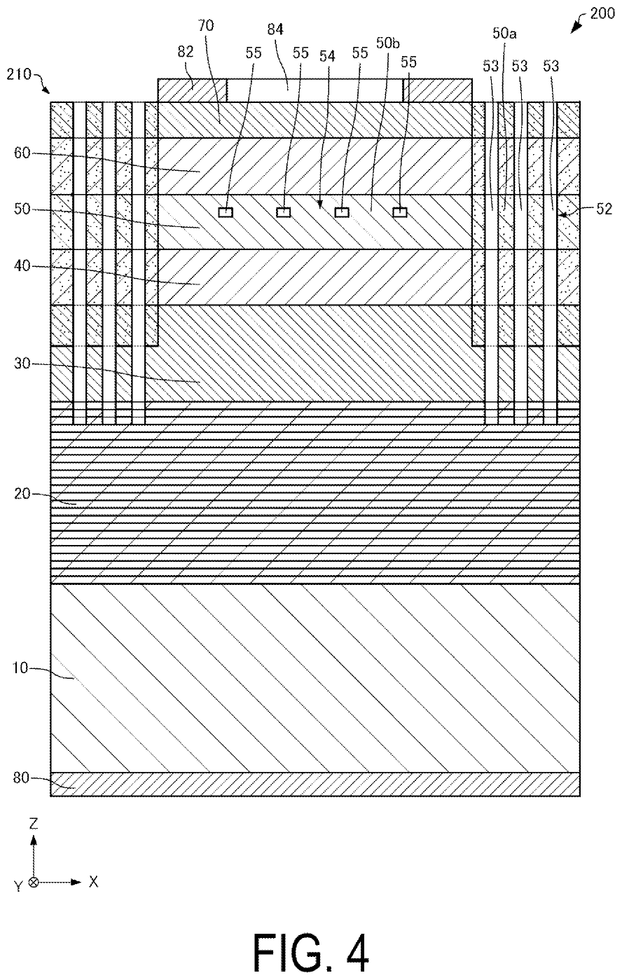

Next, a light emitting device according to a first modified example of the present embodiment will be described with reference to the drawings. FIG. 4 is a cross-sectional view schematically showing a light emitting device 200 according to the first modified example of the present embodiment.

In the following description, in the light emitting device 200 according to the first modified example of the present embodiment, members having the same functions as the constituent members of the light emitting device 100 according to the present embodiment described above will be denoted by the same reference numerals and detailed description thereof will be omitted. The same applies to light emitting devices according to second and third modified examples of the present embodiment, which will be described later.

In the above-described light emitting device 100, the first photonic crystal 52 performs the distributed feedback of the light generated in the light emitting layer 30.

On the other hand, in the light emitting device 200, the first photonic crystal 52 performs distributed reflection of the light generated in the light emitting layer 30.

As shown in FIG. 4, in the light emitting device 200, the first holes 53 penetrate from an upper surface of the contact layer 70 to the first semiconductor layer 20. In the illustrated example, bottom surfaces of the first holes 53 are located between an upper surface and a lower surface of the first semiconductor layer 20 in the laminating direction.

The light emitting device 200 has an implanted region 210 into which protons (H⁺) are implanted by ion implantation. The implanted region 210 is provided on lateral sides of the light emitting layer 30, the second semiconductor layer 40, the second region 50b of the photonic crystal layer 50, the third semiconductor layer 60, and the contact layer 70. For example, when viewed in the laminating direction, the implanted region 210 surrounds the light emitting layer 30, the second semiconductor layer 40, the second region 50b, the third semiconductor layer 60, and the contact layer 70. The first region 50a of the photonic crystal layer 50 is configured of the implanted region 210. The implanted region 210 has insulating properties.

The first holes 53 of the first photonic crystal 52 are formed in the implanted region 210. The plurality of first holes 53 form a photonic band gap due to a large refractive index difference between the semiconductor layer and the through holes.

The contact layer 70 overlaps the second region 50b when viewed in the laminating direction. The contact layer 70 does not overlap the first region 50a when viewed in the laminating direction. The second electrode 82 overlaps the second region 50b when viewed in the laminating direction. The contact layer 70 does not overlap the first region 50a when viewed in the laminating direction.

The light generated in the light emitting layer 30 is distributed and reflected in the in-plane direction by the first photonic crystal 52 and undergoes Fabry-Perot resonance in a region surrounded by the first photonic crystal 52 when viewed in the laminating direction. The second photonic crystal 54 emits Fabry-Perot resonance light, for example, in the laminating direction. In addition, when viewed in the laminating direction, light propagating in a direction separated from the second photonic crystal 54 is gradually attenuated due to the photonic band gap in the region overlapping the first photonic crystal 52.

In the light emitting device 200, the contact layer 70 does not overlap the first region 50a but overlaps the second region 50b when viewed in the laminating direction. For that reason, in the light emitting device 200, an electric current is less likely to be injected into the first photonic crystal 52, which is not a light emitting region, and thus even if dislocations or the like occur, their influence on the light is small and reliability can be improved. In addition, due to the fact that the electric current is not injected into the first region 50a, absorption may occur in the light emitting layer 30 in the region overlapping the first region 50a in a plan view. In order to inhibit this, processing such as Zn diffusion may be performed on the light emitting layer 30 in the first region 50a. Due to the Zn diffusion, the quantum well structure of the light emitting layer 30 in this region can be destroyed to reduce absorption loss.

### 3.2. Second Modified Example

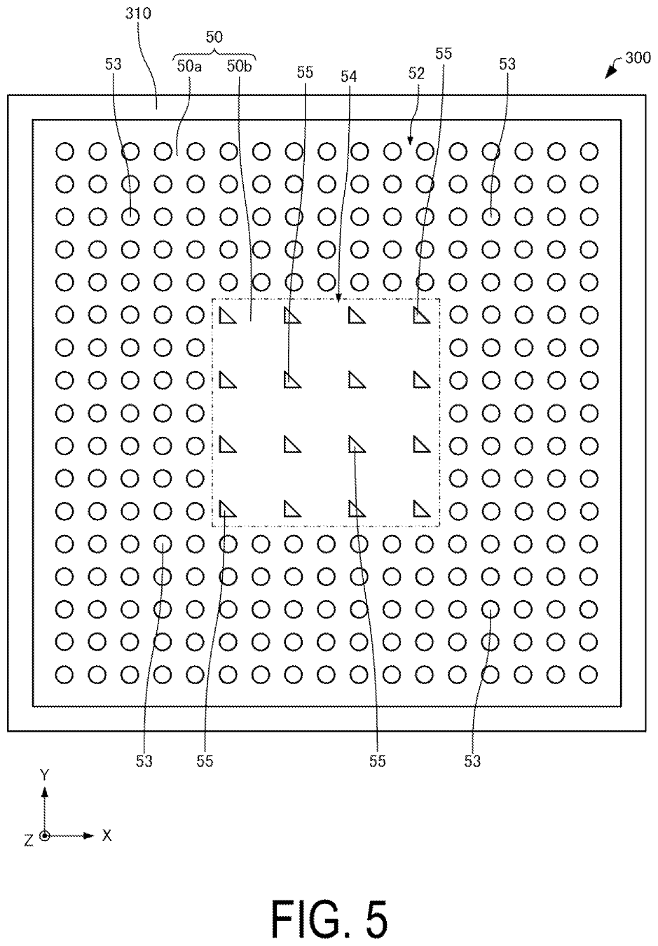

Next, a light emitting device according to a second modified example of the present embodiment will be described with reference to the drawings. FIG. 5 is a plan view schematically showing a light emitting device 300 according to the second modified example of the present embodiment.

As shown in FIG. 5, the light emitting device 300 is different from the above-described light emitting device 100 in that it has a reflecting portion 310. Also, for the sake of convenience, illustration of members other than the photonic crystal layer 50 and the reflecting portion 310 is omitted in FIG. 5.

The reflecting portion 310 surrounds the first region 50a of the photonic crystal layer 50 when viewed in the laminating direction. The reflecting portion 310 surrounds the first photonic crystal 52 when viewed in the laminating direction. The reflecting portion 310 is provided on a lateral side of the light emitting layer 30. A material of the reflecting portion 310 is, for example, a metal, a dielectric, or the like. The reflecting portion 310 is formed by, for example, a vacuum deposition method, a sputtering method, a chemical vapor deposition (CVD) method, or the like.

The reflecting portion 310 reflects the light generated in the light emitting layer 30. Specifically, the reflecting portion 310 reflects the light that is generated in the light emitting layer 30 and propagates in the direction separated from the second photonic crystal 54 when viewed in the laminating direction.

The light emitting device 300 has the reflecting portion 310 that surrounds the first region 50a when viewed in the laminating direction and reflects the light emitted by the light emitting layer 30. For that reason, in the light emitting device 300, light leaking from the first region 50a can be returned to the first region 50a when viewed in the laminating direction.

### 3.3. Third Modified Example

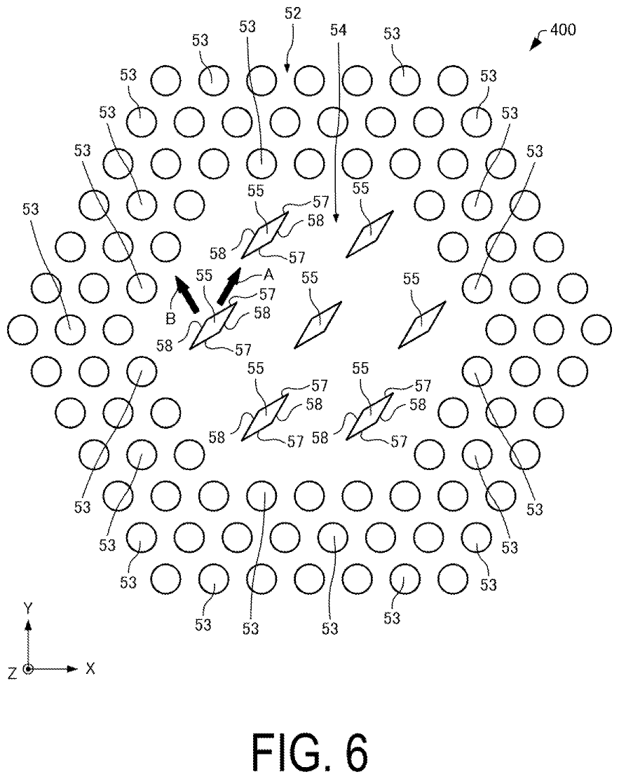

Next, a light emitting device according to a third modified example of the present embodiment will be described with reference to the drawings. FIG. 6 is a plan view schematically showing a light emitting device 400 according to the third modified example of the present embodiment. Also, for the sake of convenience, illustration of members other than the first holes 53 of the first photonic crystal 52 and the second holes 55 of the second photonic crystal 54 is omitted in FIG. 6.

As shown in FIG. 1, in the above-described light emitting device 100, the plurality of first holes 53 of the first photonic crystal 52 are arranged in a square lattice pattern when viewed in the laminating direction. The plurality of second holes 55 of the second photonic crystal 54 are arranged in a square lattice pattern.

On the other hand, in the light emitting device 400, as shown in FIG. 6, the plurality of first holes 53 are arranged in a regular triangular lattice pattern when viewed in the laminating direction. The plurality of second holes 55 are arranged, for example, in a regular triangular lattice pattern.

In the illustrated example, adjacent first holes 53 are arranged in the X axis direction. Adjacent second holes 55 are arranged in the X axis direction. When viewed in the laminating direction, the shapes of the second holes 55 are rhombic. The second holes 55 each have first inclined surfaces 57 and second inclined surfaces 58.

The first inclined surfaces 57 are inclined at 30° with respect to the X axis (with respect to the +X axis direction). For example, the first inclined surfaces 57 reflect the light propagating in the +X axis direction in a direction inclined at 60° with respect to the X axis as indicated by arrow A.

The second inclined surfaces 58 are inclined at 60° with respect to the X axis. For example, the second inclined surfaces 58 reflect the light propagating in the +X axis direction in a direction inclined at 120° with respect to the X axis as indicated by arrow B.

In the light emitting device 400, in the second photonic crystal 54, resonance in the X axis direction, resonance in the direction inclined at 60° with respect to the X axis, and resonance in the direction inclined at 120° with respect to the X axis can be coupled with one another. In this way, in the light emitting device 400, the resonance in three different directions can be coupled with one another, and two-dimensional resonance of the light can be strengthened.

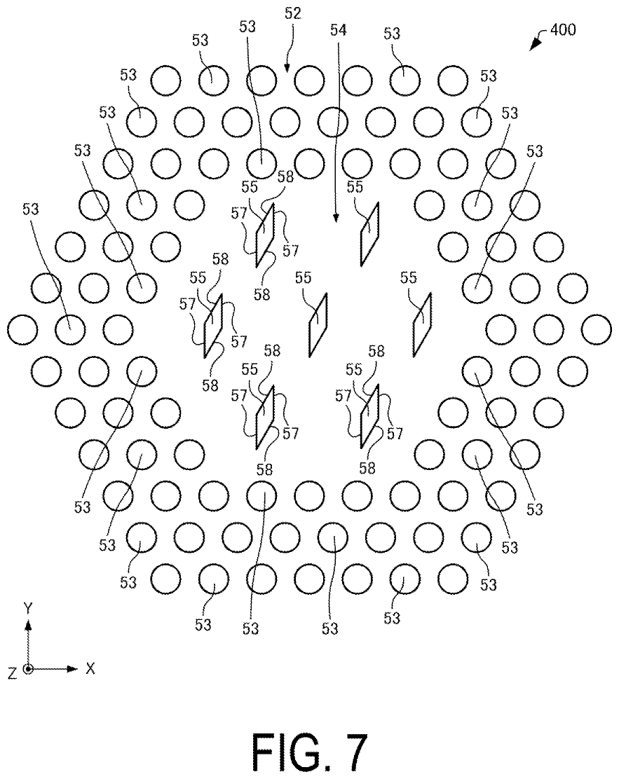

Also, inclination angles of the inclined surfaces 57 and 58 with respect to the X axis are not particularly limited as long as the resonance in three different directions can be coupled with one another. As shown in FIG. 7, when viewed in the laminating direction, the first inclined surfaces 57 may be inclined at 90° with respect to the X axis, and the second inclined surfaces 58 may be inclined at 60° with respect to the X axis. Also, although not illustrated, when viewed in the laminating direction, the first inclined surfaces 57 may be inclined at 90° with respect to the X axis, and the second inclined surfaces 58 may be inclined at 120° with respect to the X axis. Also, the first inclined surfaces 57 may be inclined at 150° with respect to the X axis, and the second inclined surfaces 58 may be inclined at 180° with respect to the X axis (that is, may be parallel to the X axis). Also, the first inclined surfaces 57 may be inclined at 30° with respect to the X axis, and the second inclined surfaces 58 may be inclined at 0° with respect to the X axis (that is, may be parallel to the X axis).

### 4. Projector

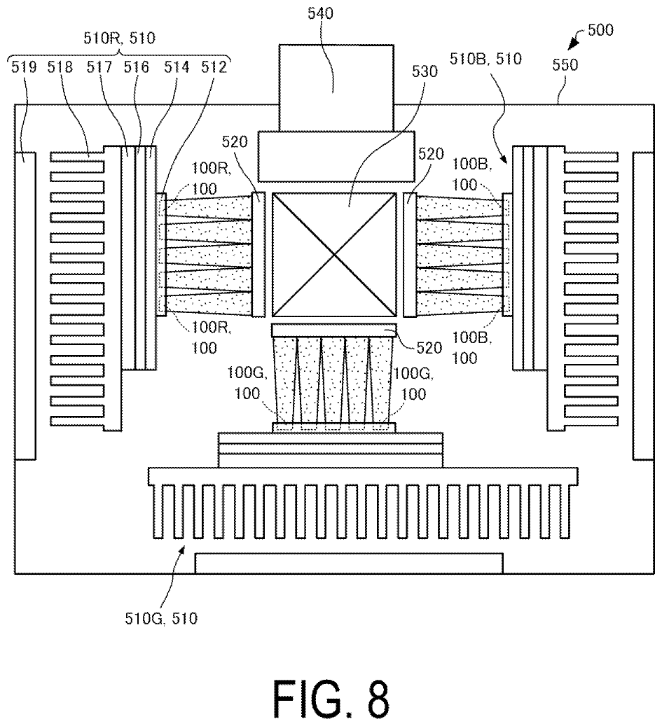

Next, a projector according to the present embodiment will be described with reference to the drawings. FIG. 8 is a diagram schematically showing a projector 500 according to the present embodiment.

As shown in FIG. 8, the projector 500 has, for example, light sources 510, light modulation devices 520, a cross dichroic prism 530, a projection device 540, and a housing 550. The projector 500 is, for example, a backlight type projector.

Three light sources 510 are provided. Among the three light sources 510, a first light source 510R emits red light. Among the three light sources 510, a second light source 510G emits green light. Among the three light sources 510, a third light source 510B emits blue light.

The light sources 510 each have, for example, a PCSEL array 512, a sub-mount 514, a base 516, a Peltier module 517, a heat sink 518, and a cooling unit 519.

The PCSEL array 512 has, for example, a plurality of light emitting devices 100. The plurality of light emitting devices 100 are arranged in arrays. The number of the plurality of light emitting devices 100 is not particularly limited. The substrate 10 of the plurality of light emitting devices 100 may be common.

The PCSEL array 512 of the first light source 510R includes, as the light emitting devices 100, first light emitting devices 100R that emit red light. The PCSEL array 512 of the second light source 510G includes, as the light emitting devices 100, second light emitting devices 100G that emit green light. The PCSEL array 512 of the third light source 510B includes, as the light emitting devices 100, third light emitting devices 100B that emit blue light.

The sub-mount 514 supports the PCSEL array 512. A material of the sub-mount 514 is, for example, SiC. The base 516 supports the sub-mount 514. The material of the sub-mount 514 is, for example, copper. The Peltier module 517 supports the sub-mount 514. The heat sink 518 supports the Peltier module 517. The cooling unit 519 cools the heat sink 518. The cooling unit 519 is, for example, a blower.

In the light source 510, heat generated in the light emitting devices 100 can be dissipated from the heat sink 518 via the sub-mount 514, the base 516, and the Peltier module 517.

Light emitted from the light source 510 is incident on the light modulation device 520. Three light modulation devices 520 are provided to correspond to the number of the light sources 510. The light modulation devices 520 modulates the incident light in accordance with image information. The light modulation devices 520 are, for example, transmissive liquid crystal light valves.

The three color lights modulated by the light modulation devices 520 are incident on the cross dichroic prism 530. The cross dichroic prism 530 is formed by bonding four right-angle prisms. A dielectric multilayer film that reflects the red light and a dielectric multilayer film that reflects the blue light are provided on an inner surface of the cross dichroic prism 530. These dielectric multilayer films combine the three color lights to form light representing a color image.

The light combined by the cross dichroic prism 530 is incident on the projection device 540. The projection device 540 projects the combined light onto, for example, a screen (not shown). The projection device 540 is, for example, a projection lens.

The housing 550 houses the light sources 510, the light modulation devices 520, the cross dichroic prism 530, and a part of the projection device 540. A material of the housing 550 is not particularly limited.

### 5. Modified Examples of Projector

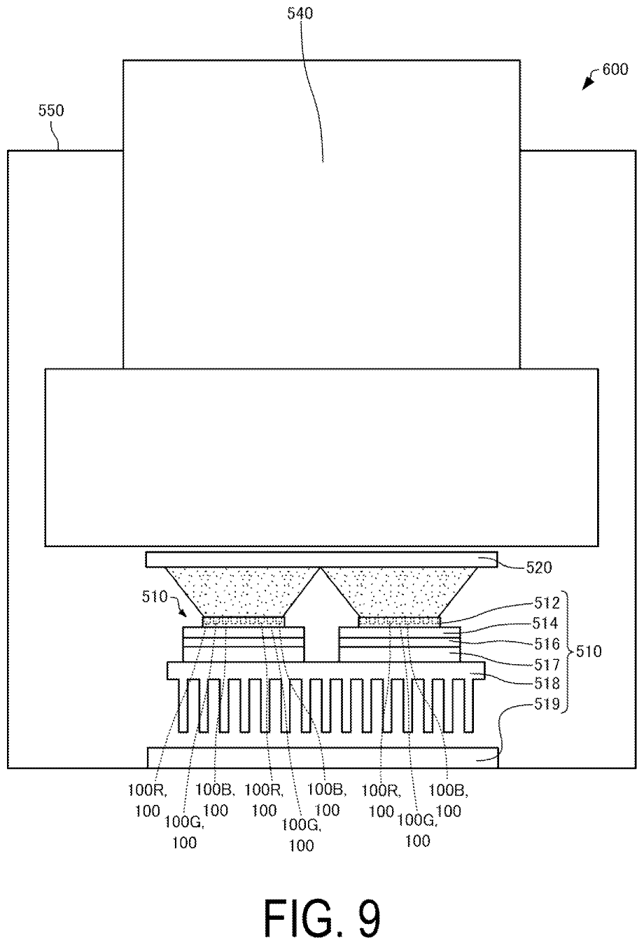

Next, a projector according to a modified example of the present embodiment will be described with reference to the drawings. FIG. 9 is a diagram schematically showing a projector 600 according to a modified example of the present embodiment.

In the following description, in the projector 600 according to the modified example of the present embodiment, members having the same functions as the constituent members of the projector 500 according to the present embodiment described above will be denoted by the same reference numerals, and detailed description thereof will be omitted.

In the projector 500 described above, as shown in FIG. 8, three light sources 510 are provided, and the first light source 510R emits red light, the second light source 510G emits green light, and the third light source 510B emits blue light.

On the other hand, in the projector 600, as shown in FIG. 9, one light source 510 emits red light, green light, and blue light. For that reason, the projector 600 can be reduced in size compared to, for example, the projector 500.

A plurality of light sources 510 are provided. In the illustrated example, the heat sink 518 of the plurality of light sources 510 is common. The cooling unit 519 of the plurality of light sources 510 is common. The PCSEL array 512 has, for example, a first light emitting device 100R that emits red light, a second light emitting device 100G that emits green light, and a third light emitting device 100B that emits blue light. The first light emitting device 100R, the second light emitting device 100G, and the third light emitting device 100B are arranged in order in a matrix, for example. The number of the plurality of light emitting devices 100 is not particularly limited. One light emitting device 100 emits light in a total of four directions inclined with respect to the laminating direction by first-order and second-order diffraction (each having the X axis direction and the Y axis direction) while resonating the light in the in-plane direction by third-order diffraction in the second photonic crystal region, for example.

Only one light modulation device 520 is provided. The light emitted from the light sources 510 is incident on the light modulation device 520. The light emitted from the light modulation device 520 is incident on the projection device 540 without passing through the cross dichroic prism.

Also, although not illustrated, an optical element such as a micro lens array or a prism may be provided in an optical path between the light sources 510 and the light modulation device 520.

Also, in the above example, a transmissive liquid crystal light valve is used for the light modulation device, but a reflective light valve may be used, or a light valve other than liquid crystal such as a digital micro mirror device may be used. In addition, a configuration of the projection device is appropriately changed depending on a type of the light valve used.

Alternatively, an image may be directly formed by controlling the light emitting devices 100 of the light sources 510 as pixels of the image in accordance with image information without using the light modulation device 520.

Further, the light source 510 can also be applied to a light source device of a scanning type image display device having a scanning means, which is an image forming device that displays an image of a desired size on a display surface by scanning light from the light source 510 on a screen.

The light emitting devices according to the embodiments described above can also be used in a projector. The light emitting devices according to the above-described embodiments are used as, for example, light sources of 3D modeling equipment, head-mounted displays, light sources for promoting structures of plants, indoor and outdoor lighting, laser printers, scanners, automotive lights, sensing devices such as pulse measuring devices that use light, light sources for communication devices, and the like.

The embodiments and modified examples described above are examples and are not intended as limiting. For example, each embodiment and each modified example can also be combined together as appropriate.

The present disclosure includes configurations that are substantially identical to the configurations described in the embodiments, for example, configurations with identical functions, methods and results, or with identical objects and effects. Also, the present disclosure includes configurations obtained by replacing non-essential portions of the configurations described in the embodiments. In addition, the present disclosure includes configurations having the same operations and effects or can achieve the same objects as the configurations described in the embodiments. Further, the present disclosure includes configurations obtained by adding known techniques to the configurations described in the embodiments.

The following content is derived from the embodiments and modified examples described above.

One aspect of a light emitting device includes:
a first semiconductor layer having a first conductivity type;
a second semiconductor layer having a second conductivity type different from the first conductivity type;
a light emitting layer disposed between the first semiconductor layer and the second semiconductor layer; and
a photonic crystal layer provided on a side of the second semiconductor layer opposite to the light emitting layer, wherein
the photonic crystal layer includes:
a first region provided with a first photonic crystal that causes light emitted by the light emitting layer to resonate in a direction orthogonal to a laminating direction of the first semiconductor layer and the light emitting layer and does not cause the light to be emitted in a direction different from the orthogonal direction; and
a second region provided with a second photonic crystal that does not overlap the first region when viewed in the laminating direction and causes the light emitted by the light emitting layer to be emitted in a direction different from the orthogonal direction.

According to this light emitting device, it is possible to reduce scattering of the light caused to resonate by the first photonic crystal due to the second photonic crystal.

In one aspect of the light emitting device, the second photonic crystal may emit the light generated in the light emitting layer in the laminating direction.

According to this light emitting device, the light generated in the light emitting layer can be emitted using first-order diffraction.

One aspect of the light emitting device may further include:
an electrode; and
a contact layer disposed between the photonic crystal layer and the electrode, wherein,
when viewed in the laminating direction, the contact layer may overlap the first region and the second region.

According to this light emitting device, the intensity of the light resonating in the in-plane direction can be increased by the first photonic crystal.

One aspect of the light emitting device may further include:
an electrode; and
a contact layer disposed between the photonic crystal layer and the electrode, wherein,
when viewed in the laminating direction, the contact layer may overlap the second region without overlapping the first region.

According to this light emitting device, an electric current is less likely to be injected into the first photonic crystal, and the reliability can be improved.

In one aspect of the light emitting device,
the first region may surround the second region when viewed in the laminating direction.

According to this light emitting device, the light caused to resonate in the in-plane direction by the first photonic crystal can be efficiently guided to the second photonic crystal.

One aspect of the light emitting device may further include a reflecting portion configured to surround the first region when viewed in the laminating direction and which reflects the light emitted by the light emitting layer.

According to this light emitting device, light leaking from the first region can be returned to the first region when viewed in the laminating direction.

In one aspect of the light emitting device,
the first photonic crystal may have a plurality of first holes arranged periodically,
the second photonic crystal may have a plurality of second holes arranged periodically, and
when viewed in the laminating direction, a shape of each of the plurality of first holes may be different from a shape of each of the plurality of second holes.

In one aspect of the light emitting device,
when viewed in the laminating direction,
a shape of each of the plurality of first holes may have rotational symmetry, and
a shape of each of the plurality of second holes may not have rotational symmetry.

According to this light emitting device, it is possible to inhibit non-luminous spots caused by the light cancelling out each other due to excessively good symmetry immediately above the light emitting device.

One aspect of a projector has the one aspect of the light emitting device.

What is claimed is:

1. A light emitting device, comprising:
a first semiconductor layer having a first conductivity type;
a second semiconductor layer having a second conductivity type different from the first conductivity type;
a light emitting layer disposed between the first semiconductor layer and the second semiconductor layer; and
a photonic crystal layer disposed on a side of the second semiconductor layer opposite to the light emitting layer, wherein
the photonic crystal layer includes:
a first region provided with a first photonic crystal that causes light emitted by the light emitting layer to resonate in a direction orthogonal to a laminating direction of the first semiconductor layer and the light emitting layer and does not cause the light to be emitted in a direction different from the orthogonal direction; and
a second region provided with a second photonic crystal that does not overlap the first region when viewed in the laminating direction and causes the light emitted by the light emitting layer to be emitted in a direction different from the orthogonal direction.

2. The light emitting device according to claim 1, wherein
the second photonic crystal emits the light generated in the light emitting layer in the laminating direction.

3. The light emitting device according to claim 1, further comprising:
an electrode; and
a contact layer disposed between the photonic crystal layer and the electrode, wherein
the contact layer overlaps the first region and the second region when viewed in the laminating direction.

4. The light emitting device according to claim 1, further comprising:
an electrode; and
a contact layer disposed between the photonic crystal layer and the electrode, wherein
the contact layer overlaps the second region without overlapping the first region when viewed in the laminating direction.

5. The light emitting device according to claim 1, wherein
the first region surrounds the second region when viewed in the laminating direction.

6. The light emitting device according to claim 5, further comprising
a reflecting portion configured to surround the first region when viewed in the laminating direction and which reflects the light emitted by the light emitting layer.

7. The light emitting device according to claim 1, wherein
the first photonic crystal has a plurality of first holes arranged periodically,
the second photonic crystal has a plurality of second holes arranged periodically, and
when viewed in the laminating direction, a shape of each of the plurality of first holes is different from a shape of each of the plurality of second holes.

8. The light emitting device according to claim 7, wherein,
when viewed in the laminating direction,
a shape of each of the plurality of first holes has rotational symmetry, and
a shape of each of the plurality of second holes does not have rotational symmetry.

9. A projector comprising the light emitting device according to claim 1.
